(19) United States
(12) Patent Application Publication
(10) Pub. No.: US 2024/0057301 A1
(43) Pub. Date: Feb. 15, 2024

(54) Passive Thermal Transport Network for Power Supply

(71) Applicant: AA Power Inc., Boston, MA (US)

(72) Inventor: Qun Lu, Lexington, MA (US)

(21) Appl. No.: 18/232,943

(22) Filed: Aug. 11, 2023

Related U.S. Application Data
(60) Provisional application No. 63/397,039, filed on Aug. 11, 2022.

(51) Int. Cl. H05K 7/20

(52) U.S. Cl. CPC H05K 7/209; H05K 7/20518; H05K 7/20936

(57) ABSTRACT

A power supply for providing power to a power consumer includes comprising power-handling circuitry disposed in a housing that comprises a shell and a heat guide. The shell has an outer surface and an inner surface. The inner surface has a heat guide disposed therein. The heat guide has a higher thermal conductivity than that of the outer surface. The shell passively dissipates heat generated by the power-handling circuitry at a rate sufficient to maintain the power-handling circuitry at an operating temperature.

### RELATED APPLICATIONS

This application claims the benefit of the Aug. 11, 2022 priority date of U.S. Provisional Application 63/397,039, the content of which is incorporated herein by reference.

### TECHNICAL FIELD

The invention concerns power supplies, and in particular, cooling a power supply.

### BACKGROUND

A power supply for use by a server in a data center includes circuitry that converts power into a form suitable for use by that server. An unfortunate side effect of doing so is the generation of heat. Since excessive heat accumulation is undesirable, it is usual to provide a cooling mechanism. A typical power supply uses a fan to promote heat dissipation.

Fans are commonly used to cool power supplies. However, fans increase both the cost of the power supply as well as its power consumption. Power supply fans are also vulnerable to breaking down. This can lead to field failures.

Although a fan is effective at heat dissipation, it carries some disadvantages. First, the fan itself has a cost. Secondly, the fan requires additional power to spin. Third, the fan, like any mechanical part, is vulnerable to breakdown. Fourth, the fan draws air into the power supply, which in turn means that the components are exposed to dust, moisture, and other undesirable objects. And fifth, a fan creates noise. When many mining rigs are present, this noise can be deafening.

It is also possible to use a liquid cooling system in lieu of a fan. While this avoids the problems of dust, a liquid cooling system is also vulnerable to breakdown. For example, in a liquid cooling system, one replaces the fan with a liquid pump, which, like a fan, can break down and also consume power. Moreover, the need to provide coolant and piping to convey the coolant imposes considerable cost and creates further opportunities for failure, for example due to leakage. This further increases the cost associated with liquid cooling.

Of all the components one finds in a typical data center, the power supply is by far the most vulnerable to failure. The expected lifetime of a power supply is significantly shorter than that of other data center equipment. This is particularly unfortunate because failure of a power supply has a cascading effect. When a power supply fails, everything that relies on that power supply also fails.

To make matters worse, the act of replacing a failed power supply is a costly one. Based on labor and equipment cost and lost productivity, it has been estimated that the cost of replacing a failed power supply is at least twice or even four times as much as the cost of the power supply itself. Added to this is the additional effort required to make a power supply hot-swappable.

The circuitry that forms the power supply is not, in itself, unreliable. The culprit is, in most cases, the reliance on an active cooling system that moves a fluid, whether the fluid is in gaseous form, in which case one uses a fan, or whether it is in liquid form, in which case one uses a pump. Were it not for the active cooling system, and its proclivity for failure, a power supply's lifetime could be extended significantly.

Unfortunately, it is difficult to eliminate either the fan or some other active cooling mechanism that relies on a mechanical part (such as a fan or a pump) that is prone to failure. The difficulty in eliminating such a part arises from the sheer quantity of heat that is produced during normal operation of a power supply. This is because the rate at which heat is generated relative to the rate at which it is dissipated is such that the steady-state solution to the heat equation places the components at a temperature that is higher than their operating temperature.

The semiconductor devices that populate a typical power supply are notoriously sensitive to temperature. For example, certain fundamental material properties of semiconductors, such as charge-carrier mobility, are strongly dependent on temperature. Thus, it has been found that, without some active movement of cooling fluid, whether that fluid be gas or liquid, the equilibrium temperature of the components during normal operation settles at a point that is high enough for the components to fail.

### SUMMARY

The invention provides a heat dissipation path for a passive dissipation of heat in a power supply. The path extends from one or more heat-generating devices to heat-dissipation shell. As a result, the path uses the large exterior area of the heat dissipation shell for dissipating heat, for example by radiation and/or conduction. The path also includes one or more thermally-conductive paths that extend from the heat-generating devices to more remote areas of the shell that are far from the heat-generating devices. This makes it possible to use more than merely that portion of the shell that is local to the heat-generating device.

In one embodiment, the shell comprises an inner layer and an outer layer.

The inner layer is made of material having a particularly high thermal conductivity and/or inlays, such as heat pipes or homogeneous plates, that have particularly high thermal conductivity components. The outer part can have a slightly lower thermal conductivity in order to reduce costs. The outer layer has an outer surface that has been treated to increase the rate at which the surface emits thermal radiation, for example through anodizing or through being coated with a planar allotrope of carbon. In some embodiments, the outer layer is coated with graphene.

In some embodiments, the shell's outer layer is made of aluminum, an aluminum alloy, copper or other materials with a high thermal conductivity and emissivity. Among these are embodiments in which the shell's outer layer has a surface that has been treated to increase its emissivity, for example by spraying carbon nano powder, graphene or by anodizing it.

Embodiments further include those in which the shell's inner layer is made of copper or an alloy thereof such that the inner layer's thermal conductivity exceeds that of the outer layer.

In other embodiments, the inner layer includes a recess with an inlay embedded therein. Suitable inlays include heat pipes, heat equalization plates, or other components with a higher thermal conductivity.

During operation of the power supply, the high thermal-conductivity material in the inner layer conducts the heat from heat-generating devices and distributes it throughout the entire shell, including to those regions of the shell that are remote from the heat-generating devices. As a result, the power supply is able to use an exceptionally large area having high emissivity for dissipation of heat, instead of being limited to a local area near the heat-generating device.

In one aspect, the invention features an apparatus comprising a power supply for providing power to one or more power consumers. Such a power supply includes power-handling components disposed in a housing that comprises a shell and one or more heat guides. The shell has an outer surface and an inner surface. The outer surface is made from a material having a first thermal conductivity and the inner surface is in thermal contact with the power-handling components. Heat guides are disposed on or in the inner surface. The one or more heat guides transport heat along a component-density gradient from a proximal zone of the shell to a distal zone of the shell at a rate sufficient to maintain the power-handling components at or below a particular operating temperature. During operation of the power supply, the distal zone is at a lower temperature than the proximal zone.

In some embodiments, the power supply is an ac/dc power supply. However, other embodiments include dc/dc power supplies, dc/ac power supplies, and ac/ac power supplies.

Among the embodiments are those in which the one or more heat guides comprise solid-state thermal paths having a second thermal conductivity. In such embodiments, the second thermal conductivity exceeds the first thermal conductivity. In some of these embodiments, the inner wall also includes a recess in which a solid-state thermal path is embedded or inlaid.

In still other embodiments, the one or more heat guides comprise a fluid-filled chamber that is disposed to draw heat from the power-handling components. In such embodiments, the power-handling components provide thermal energy for causing fluid in the fluid-filled chamber to transition into vapor that migrates towards a cooler portion of the fluid-filled chamber.

Further embodiments include those in which the shell's outer surface has been treated to increase a ratio of thermal energy emitted by the outer surface to that emitted by a black body at the same temperature as the outer surface. Examples include those in which the shell comprises an outer surface made of aluminum oxide, such as that obtained after having anodized aluminum.

Still other embodiments include those in which inner wall of the shell comprises a planar allotrope of carbon, those in which it comprises graphene, and those in which the inner wall comprises a material having an anisotropic thermal conductivity.

Also among the embodiments in which the power consumers are in a data center and those in which the power consumer is a stand-alone server.

Further embodiments include those in which the heat guide is in an intermediate layer of the shell between the inner and outer surfaces thereof and those in which the heat guide is on the inner surface of said shell.

As used herein, a “power supply” includes power supplies used in stand-alone servers and power supplies used in a data center, including those in which gas serves as a heat-transport medium, those in which liquid serves as a heat-transport medium, air-cooled power supplies, and liquid-cooled power supplies.

These and other features of the invention will be apparent from the following detailed description and the accompanying figures, in which:

### DESCRIPTION OF DRAWINGS

FIG. 1 shows a section of a shell of a power supply;

FIG. 2 shows an exploded view of a shell of a power supply in which recesses for heat guides are visible;

FIG. 3 shows an assembled view of the shell shown in FIG. 2 in which the heat guides have been inlaid in the recesses;

FIG. 4 shows a cross section of the shell shown in FIG. 3; and

FIG. 5 shows a shell having a lateral heat guide.

### DETAILED DESCRIPTION

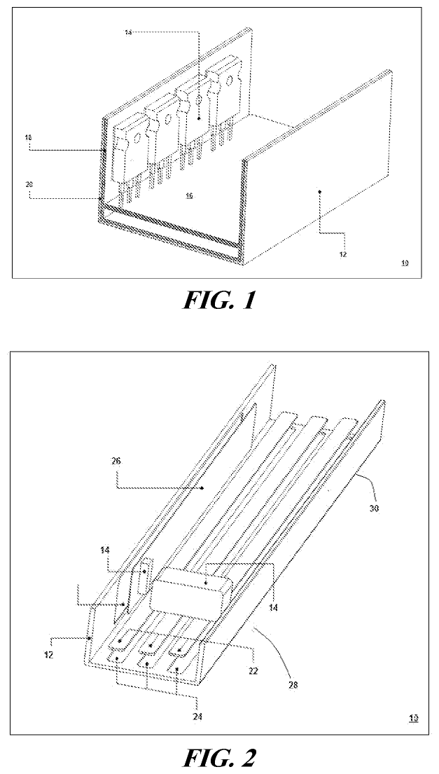

FIG. 1 shows a section of a power supply 10 having a shell 12. Within the power supply are various power-handling components 14 that are connected to a printed-circuit board 16. These power-handling components 14 are electronic components that, in operation, generate considerable amounts of waste heat. This waste heat is to be dissipated at a rate that matches or exceeds its production so as to avoid having the power-handling components 14 operating at elevated temperatures that may, in the long run, damage them.

The power-handling components 14 are in thermal contact with an inner wall 18 of the shell 12. The inner wall 18 is likewise in thermal communication with an outer wall 20 of the shell 12.

In some embodiments, there exist one or more additional layers of material between the inner wall 18 and the outer wall 20. Among these are embodiments in which one layer promotes rapid heat transfer and another layer suppresses electromagnetic interference. Among these are embodiments in which an inside layer is an electromagnetic interference isolation layer. In some cases, one or more layers are thermally conductive but not electrically conductive.

The outer wall 20 is selected so as to emit thermal radiation at a rate that is as close as possible to that emitted by a black body at the same temperature as the outer wall 20. Useful materials for use as an outer wall include a metal that has been oxidized, for example by having undergone an anodization process. Suitable metals that, when oxidized, are useful for an outer wall 20 include aluminum and copper. Also useful are various transition metal disilicides.

The inner wall 18 comprises a material having a thermal conductivity that is higher than that of the outer wall 20. As an example, for an outer wall 20 that comprises aluminum or an alloy thereof, a useful material for the corresponding inner wall 18 would be copper, an alloy that comprises copper, or a planar allotrope of carbon having anisotropic thermal conductivity.

An anisotropic thermal conductor is particularly useful, particularly if conductivity is higher in a planar direction than it is in a perpendicular direction. Such a material promotes guidance of heat in the transverse direction along the shell's wall and away from the power-handling components 14.

A planar allotrope of carbon is particularly useful because its thermal conductivity, which is anisotropic, is as high as 1,500 watts per meter per degree kelvin in its preferred direction. This preferred direction is in the plane defined by the hexagons formed by the carbon atoms. Coating the shell 12 thus aligns this preferred direction to be in the plane of the shell 12. This makes it possible to use such a substance to rapidly transfer heat through the shell 12.

In another embodiment, an exploded view of which is shown in FIG. 2, the shell 12 features one or more heat guides. A variety of implementations exist for a heat guide.

FIG. 2 shows a heat guide implemented as a solid-state thermal path 22 that is inlaid into a corresponding recess 24 on the floor of the shell 12. However, in other embodiments, the thermal path 22 is inlaid into a recess in another wall of the shell 12. Still other embodiments feature thermal paths 22 inlaid into recesses of different walls of the shell 12.

The solid-state thermal path 22 comprises a solid having a thermal conductivity greater than that of the shell 12. In a preferred embodiment, the material is selected to have a thermal conductivity greater than a kilowatt per meter per degree kelvin. In a particularly preferred embodiment, the material is selected to have a thermal conductivity in excess of five kilowatts per meter per degree kelvin. Suitable materials for achieving such conductivities include allotropes of carbon, such as tetrahedral carbon or carbon that is arranged to form a hexagonal lattice.

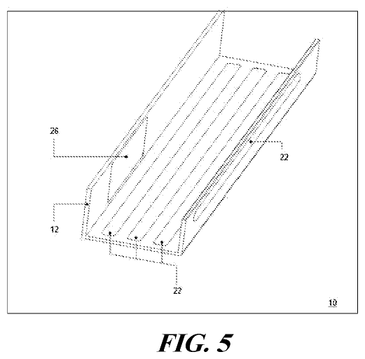

The solid-state thermal path 22 takes the form of a pipe, strip, or plate. The embodiment shown in FIG. 2 includes three such recesses 24 and three corresponding solid-state thermal paths 22. The number, placement, and configuration of these solid-state thermal paths 22 and their corresponding recesses 24 is exemplary only and is dictated by the geometry of the shell 12 and the placement of the power-handling components 14. For example, in the embodiment shown in FIG. 5, a solid-state thermal path 24 has been placed on a lateral wall of the shell 12. FIG. 2 also shows a heat guide implemented as a dual-phase heat transporter 26. The dual-phase heat transporter 26 comprises a fluid-filled chamber filled with a fluid that transitions between a liquid phase and a vapor phase. The portion of the dual-phase heat transporter 26 in contact with the power-handling components 14 draws thermal energy from those power-handling components 14 and uses it to cause the fluid to transition into the vapor phase. The fluid in the vapor phase then migrates away from the power-handling components 14, taking with it the latent heat of evaporation provided by the power-handling components 14. As it migrates to a cooler portion of the shell 12, it condenses, thus releasing the latent heat that it drew from the power-handling components 14 so that it can be dissipated into the environment.

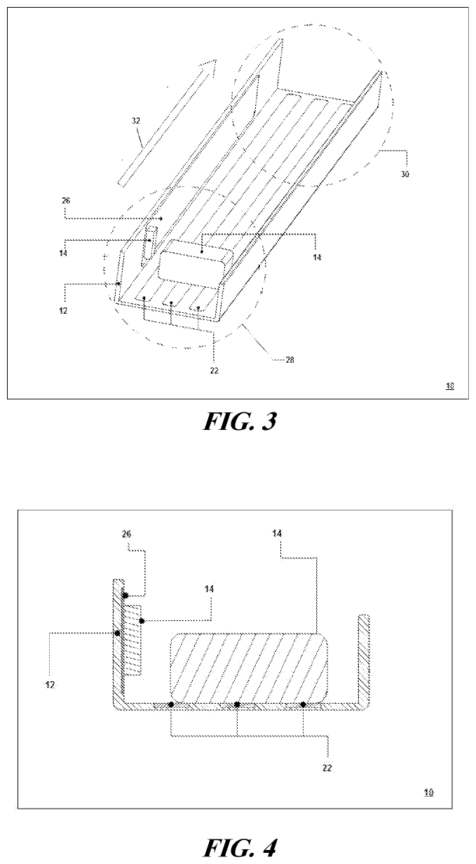

FIGS. 3 and 4 shows an assembled view of the structure shown in FIG. 2 in which the solid-state thermal paths 22 have been inlaid into the recesses 24. As shown in FIGS. 3-4, the thermal paths 22 are inlaid in an inner wall. However, in some embodiments, the thermal paths 22 extend through an intermediate layer between the inner wall and an outer wall of the shell 12.

As shown in FIG. 3, the shell 12 comprises an internal volume that consists of a first volume and a second volume. The first volume is that which is occupied by the power-handling components 14. The second volume is that volume that is not occupied by the power-handling components 14. It is therefore possible to define, for any finite volume within the internal volume, a ratio of the first volume to the internal volume. This will be referred to herein as the “component density.”

It is useful to define a Cartesian coordinate system to refer to points within the shell 12. Such a coordinate system consists of first and second transverse axes that define transverse coordinates and a longitudinal axis that defines a longitudinal coordinate that extends along the direction defined by the solid-state thermal paths 22 and that is perpendicular to a plane defined by the transverse axes. It is therefore possible to define a transverse volume that consists of all points that have a longitudinal coordinate within an infinitesimal interval along the longitudinal axis. Within this transverse volume, it is possible to define a component density for that transverse volume. As can be seen in FIGS. 2 and 3, this component density decreases with increasing longitudinal coordinate. Stated differently, the power-handling components 14 are clustered on one end of the shell 12 at the proximal zone 28 and the distal zone 30 is substantially free of any power-handling components 14.

As is apparent from FIGS. 2 and 3, the heat guides, i.e., the solid-state thermal path 22 and the dual-phase heat transporter 26, extend from the proximal zone 28 all the way through the distal zone 30. As a result, the guides 24 rapidly transport heat along a component-density gradient 30 towards the distal zone 28 and away from the power-handling components 14 from a zone of high component density to a zone of lower component density. The large area of the distal zone 28 permits rapid dissipation of heat that has been transported thereto using the heat guides. In effect, the heat guides form a thermal superhighway that rapidly transports heat away from a region of high component density to a region of low component density to promote rapid dissipation thereof.

Having described the invention and a preferred embodiment thereof, what is new and secured by letters patent is:

What is claimed is:

1. An apparatus comprising a power supply for providing power to a power consumer, said power supply comprising power-handling components disposed in a housing comprising a shell and a heat guide, said shell having an outer surface and an inner surface, said outer surface being made from a material having a first thermal conductivity and said inner surface being in thermal contact with said power-handling components and having said heat guide disposed therein, wherein said heat guide transports heat along a component-density gradient from a proximal zone of said shell to a distal zone of said shell at a rate sufficient to maintain said power-handling components at or below a particular operating temperature and wherein, during operation of said power supply, said distal zone is at a lower temperature than said proximal zone.

2. The apparatus of claim 1, wherein said heat guide comprises a solid-state thermal paths having a second thermal conductivity, wherein said second thermal conductivity exceeds said first thermal conductivity.

3. The apparatus of claim 1, wherein said inner wall comprises a recess and wherein a solid-state thermal path is embedded in said recess, said solid-state thermal path having a thermal conductivity in excess of said first thermal conductivity.

4. The apparatus of claim 1, wherein said heat guide is in an intermediate layer of said shell between said inner and outer surfaces thereof.

5. The apparatus of claim 1, wherein said heat guide is on said inner surface of said shell.

6. The apparatus of claim 1, wherein said power supply is an ac/dc power supply.

7. The apparatus of claim 1, wherein said heat guide comprises a fluid-filled chamber that is disposed to draw heat from said power-handling components, wherein said power-handling components provide thermal energy for causing fluid in said fluid-filled chamber to transition into vapor that migrates towards a cooler portion of said fluid-filled chamber.

8. The apparatus of claim 1, wherein said heat guide is inlaid in said inner surface.

9. The apparatus of claim 1, wherein said shell comprises an outer surface that has been treated to increase a ratio of thermal energy emitted by the outer surface to that emitted by a black body at the same temperature as the outer surface.

10. The apparatus of claim 1, wherein said shell comprises an outer surface made of anodized aluminum.

11. The apparatus of claim 1, wherein said inner wall of said shell comprises a planar allotrope of carbon.

12. The apparatus of claim 1, wherein said inner wall of said shell comprises a material having an anisotropic thermal conductivity.

13. The apparatus of claim 1, wherein said power consumer is in an internet data center.

14. The apparatus of claim 1, wherein said power consumer is in a stand-alone server.

15. The apparatus of claim 1, wherein said power supply is a liquid-cooled power supply.

16. The apparatus of claim 1, wherein said power supply is an air-cooled power supply.

17. The apparatus of claim 1, wherein said shell is configured to suppress electromagnetic interference that arises during operation of said power supply.

18. The apparatus of claim 1, wherein said heat guide is one of a plurality of heat guides that are on different walls of said shell.

19. A method comprising dissipating heat from a power supply that is providing power to a power consumer, said method comprising using a heat guide to guide heat generated by power-handling components disposed in a housing that comprises a shell, said shell having an outer surface and an inner surface, said outer surface being made from a material having a first thermal conductivity and said inner surface being in thermal contact with said power-handling components and having said heat guide disposed therein, wherein using said heat guide comprises transporting heat along a component-density gradient from a proximal zone of said shell to a distal zone of said shell at a rate sufficient to maintain said power-handling components at or below a particular operating temperature and whereby, during operation of said power supply, said distal zone is at a lower temperature than said proximal zone.

20. The method of claim 19, wherein the power supply is an ac/dc power supply.
